(19) United States
(12) Patent Application Publication
(10) Pub. No.: US 2025/0232909 A1
(43) Pub. Date: Jul. 17, 2025

(54) ELECTRONIC COMPONENT

(71) Applicant: TDK Corporation, Tokyo (JP)

(72) Inventors: Kazuhiro TSUKAMOTO, Tokyo (JP); Takuya SATO, Tokyo (JP)

(73) Assignee: TDK Corporation, Tokyo (JP)

(21) Appl. No.: 19/012,901

(22) Filed: Jan. 8, 2025

(30) Foreign Application Priority Data
Jan. 15, 2024 (JP) 2024-003785

(51) Int. Cl. H01F 27/28; H01F 27/32; H01G 4/30

(52) U.S. Cl. CPC H01F 27/2804; H01F 27/323; H01G 4/30; H01F 2027/2809

(57) ABSTRACT

An electronic component includes a first main body and a second main body. The second main body is mounted on a first surface of the first main body. The first main body includes a first region that overlaps the second main body when viewed in a stacking direction, and a second region that does not overlap the second main body when viewed in the stacking direction. At least a part of the plurality of capacitor conductors is disposed in the first region. At least one inductor conductor includes a major part disposed in the second region, and a non-major part. The non-major part is disposed in the second region, or is disposed at least in part in the first region.

### CROSS-REFERENCE TO RELATED APPLICATION

This application claims the benefit of Japanese Priority Patent Application No. 2024-003785 filed on Jan. 15, 2024, the entire contents of which are incorporated herein by reference.

### BACKGROUND

The disclosure relates to an electronic component including a main body and mounted components mounted to the main body.

Filters, such as a low-pass filter, a high-pass filter, and a band-pass filter, are constituted using a plurality of resonators. Known as resonators used in these filters are, for example, an LC resonator constituted using an inductor and a capacitor, and an acoustic wave resonator constituted using an acoustic wave element. An acoustic wave element is an element that uses elastic waves. Acoustic wave elements include a surface acoustic wave element that uses surface acoustic waves and a bulk acoustic wave element that uses bulk acoustic waves.

Filter devices include those constituted using only an LC resonator or only an acoustic wave resonator, as well as hybrid-type filter devices constituted using an LC resonator and an acoustic wave resonator. For example, International Publication No. 2019/065027 discloses a hybrid filter device with an acoustic wave device including an acoustic wave resonator, and a passive device including an inductor element or an inductor element and a capacitive element.

A hybrid-type filter device is generally divided into a first component including an acoustic wave resonator, and a second component including other components. There may be a single second component or a plurality of second components. From the viewpoint of miniaturizing the filter device, it is preferable to mount one of the first component and the second component on the other of the first component and the second component. However, when the second component includes an inductor, there were cases where electromagnetic fields interact between the inductor and the first component depending on the shape and layout of the inductor, resulting in failure to obtain the desired characteristics.

The above-described problem is not limited to a case where the first component includes an acoustic wave resonator, but also applies a case where the first component includes any active element such as a high frequency switch, or any passive element.

### SUMMARY

An electronic component according to one embodiment of the disclosure includes: a first main body including a plurality of dielectric layers stacked together, a plurality of conductors, and a first circuit constituted using the plurality of conductors; and a second main body including a second circuit connected to the first circuit. The first main body includes a first surface located at an end of the plurality of dielectric layers in a stacking direction. The second main body is mounted on the first surface. The first main body includes a first region that overlaps the second main body when viewed in the stacking direction, and a second region that does not overlap the second main body when viewed in the stacking direction. The plurality of conductors include a plurality of capacitor conductors to constitute at least one capacitor, and at least one inductor conductor to constitute at least one inductor. At least a part of the plurality of capacitor conductors is disposed in the first region. The at least one inductor conductor includes a major part disposed in the second region, and a non-major part. The non-major part is disposed in the second region, or is disposed at least in part in the first region.

Other and further objects, features, and advantages of the disclosure will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a circuit diagram showing a circuit configuration of an electronic component according to a first example embodiment of the disclosure.

FIG. 2 is a perspective view showing the electronic component according to the first example embodiment of the disclosure.

FIG. 3 is a perspective view showing a first main body in the first example embodiment of the disclosure.

FIG. 4 is a perspective view showing the first main body in the first example embodiment of the disclosure.

FIGS. 5A to 5C are explanatory diagrams showing respective patterned surfaces of first to third dielectric layers in the first main body shown in FIGS. 2 to 4.

FIG. 6A is an explanatory diagram showing a patterned surface of a fourth dielectric layer in the first main body shown in FIGS. 2 to 4.

FIG. 6B is an explanatory diagram showing a patterned surface of each of fifth and sixth dielectric layers in the first main body shown in FIGS. 2 to 4.

FIG. 6C is an explanatory diagram showing a patterned surface of a seventh dielectric layer in the first main body shown in FIGS. 2 to 4.

FIG. 7A is an explanatory diagram showing a patterned surface of each of eighth and ninth dielectric layers in the first main body shown in FIGS. 2 to 4.

FIGS. 7B and 7C are explanatory diagrams showing respective patterned surfaces of tenth and eleventh dielectric layers in the first main body shown in FIGS. 2 to 4.

FIGS. 8A to 8C are explanatory diagrams showing respective patterned surfaces of twelfth to fourteenth dielectric layers in the first main body shown in FIGS. 2 to 4.

FIGS. 9A to 9C are explanatory diagrams showing respective patterned surfaces of fifteenth to seventeenth dielectric layers in the first main body shown in FIGS. 2 to 4.

FIGS. 10A and 10B are explanatory diagrams showing respective patterned surfaces of eighteenth and nineteenth dielectric layers in the first main body shown in FIGS. 2 to 4.

FIG. 10C is an explanatory diagram showing an electrode formation surface of the nineteenth dielectric layer.

FIG. 11 is a perspective view showing inside of the first main body in the first example embodiment of the disclosure.

FIG. 12 is a plan view showing a part of the inside of the first main body in the first example embodiment of the disclosure.

FIG. 13 is a plan view showing another part of the inside of the first main body in the first example embodiment of the disclosure.

FIG. 14 is a sectional view showing the electronic component according to the first example embodiment of the disclosure.

FIG. 15 is a characteristic chart showing an example of pass attenuation characteristics of the electronic component according to the first example embodiment of the disclosure.

FIG. 16 is a side view showing an electronic component according to a second example embodiment of the disclosure.

### DETAILED DESCRIPTION

An object of the disclosure is to provide an electronic component that includes a main body and mounted components mounted to the main body, and that can be miniaturized while achieving desired characteristics.

In the following, some example embodiments and modification examples of the disclosure will be described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

### First Example Embodiment

First, a schematic configuration of an electronic component 1 according to a first example embodiment of the disclosure will be described. The electronic component 1 according to the example embodiment is a band-pass filter that selectively passes signals of frequencies within a predetermined passband.

The electronic component 1 according to the example embodiment is a so-called hybrid-type filter that includes at least one LC resonator constituted using at least one inductor and at least one capacitor, and an acoustic wave resonator constituted using at least one acoustic wave element. Examples of the at least one acoustic wave element may include a bulk acoustic wave element and a surface acoustic wave element.

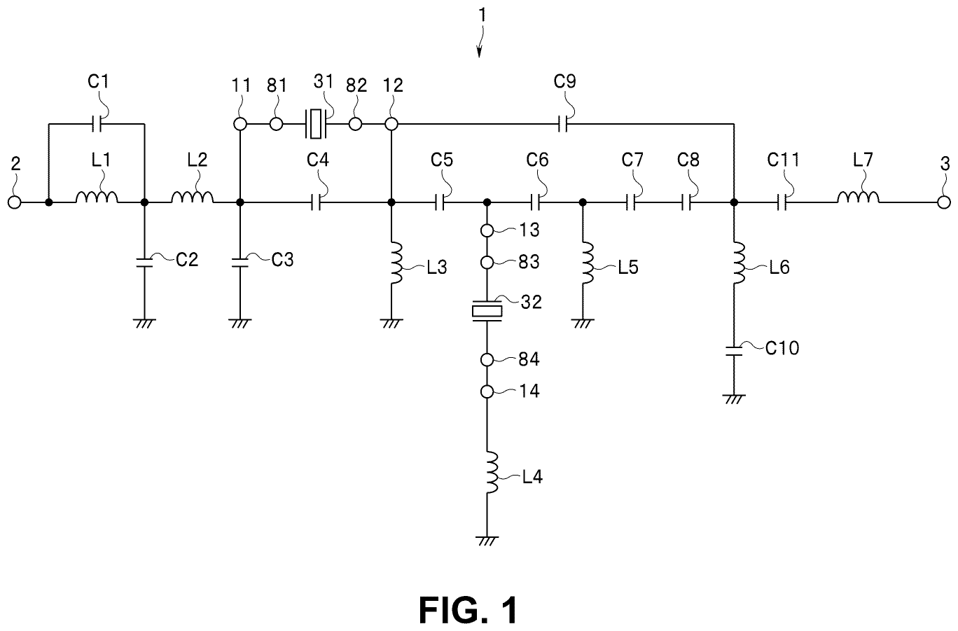

Next, an example of a circuit configuration of the electronic component 1 will be described with reference to FIG. 1. FIG. 1 is a circuit diagram showing the circuit configuration of the electronic component 1. The electronic component 1 includes a first input and output terminal 2, a second input and output terminal 3, and a first circuit provided between the first input and output terminal 2 and the second input and output terminal 3 in a circuit configuration. Note that in the present application, the expression “in the (a) circuit configuration” is used to indicate layout in the circuit diagram, not layout in the physical configuration.

Each of the first and second input and output terminals 2 and 3 is a terminal for input or output of a signal. In other words, when a signal is input to the first input and output terminal 2, the signal is output from the second input and output terminal 3. When a signal is input to the second input and output terminal 3, the signal is output from the first input and output terminal 2.

The first circuit includes inductors L1, L2, L3, L5, L6, and L7, and capacitors C1, C2, C3, C4, C5, C6, C7, C8, C9, C10, and C11. One end of the inductor L1 is connected to the first input and output terminal 2. One end of the inductor L2 is connected to the other end of the inductor L1.

One end of the capacitor C4 is connected to the other end of the inductor L2. One end of the capacitor C5 is connected to the other end of the capacitor C4. One end of the capacitor C6 is connected to the other end of the capacitor C5. One end of the capacitor C7 is connected to the other end of the capacitor C6. One end of the capacitor C8 is connected to the other end of the capacitor C7.

One end of the capacitor C11 is connected to the other end of the capacitor C8. One end of the inductor L7 is connected to the other end of the capacitor C11. The other end of the inductor L7 is connected to the second input and output terminal 3.

The capacitor C1 is connected in parallel with the inductor L1. One end of the capacitor C2 is connected to a connection point between the inductor L1 and the inductor L2. One end of the capacitor C3 is connected to a connection point between the inductor L2 and the capacitor C4. The other end of each of the capacitors C2 and C3 is connected to the ground.

One end of the inductor L3 is connected to a connection point between the capacitor C4 and the capacitor C5. One end of the inductor L5 is connected to a connection point between the capacitor C6 and the capacitor C7. The other end of each of the inductors L3 and L5 is connected to the ground.

One end of the inductor L6 is connected to a connection point between the capacitor C8 and the capacitor C11. One end of the capacitor C10 is connected to the other end of the inductor L6. The other end of the capacitor C10 is connected to the ground.

One end of the capacitor C9 is connected to one end of the capacitor C5. The other end of the capacitor C9 is connected to the other end of the capacitor C8.

The electronic component 1 further includes a second circuit connected to the first circuit. The second circuit includes signal terminals 81, 82, 83, and 84, an acoustic wave element 31 disposed between the signal terminal 81 and the signal terminal 82 in the circuit configuration, and an acoustic wave element 32 disposed between the signal terminal 83 and the signal terminal 84 in the circuit configuration.

The first circuit further includes signal terminals 11, 12, 13, and 14 connected to the signal terminals 81, 82, 83, and 84, respectively. Note that in FIG. 1, for convenience, the signal terminal 12 is drawn as interposed between the one end of the capacitor C9 and the one end of the capacitor C5. However, the signal terminal 12 may not be interposed between the one end of the capacitor C9 and the one end of the capacitor C5.

The capacitor C4 is connected in parallel with the acoustic wave element 31. The other end of the inductor L2 and one end of each of the capacitors C3 and C4 are connected to one end of the acoustic wave element 31 through the signal terminals 11 and 81 in order. The one end of the inductor L3, the other end of the capacitor C4, and the one end of the capacitor C5 are connected to the other end of the acoustic wave element 31 through the signal terminals 12 and 82 in order.

The other end of the capacitor C5 and one end of the capacitor C6 are connected to one end of the acoustic wave element 32 through the signal terminals 13 and 83 in order. The first circuit further includes an inductor L4. One end of the inductor L4 is connected to the other end of the acoustic wave element 32 through the signal terminals 14 and 84 in order. The other end of the inductor L4 is connected to the ground.

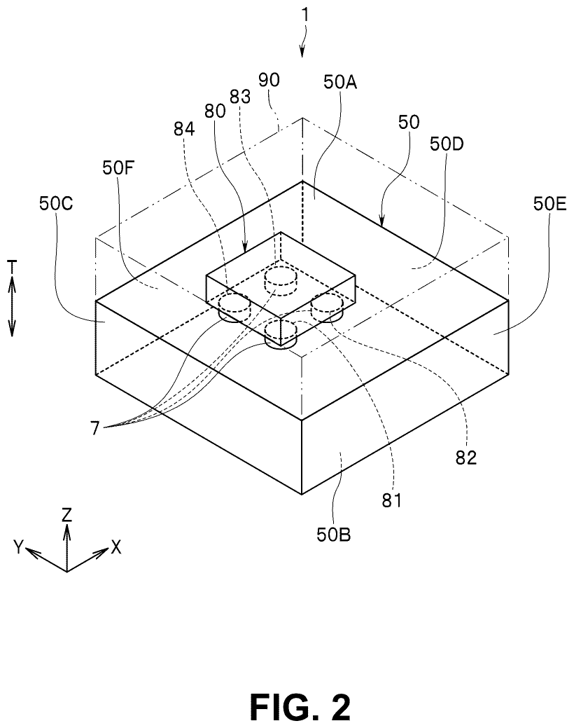

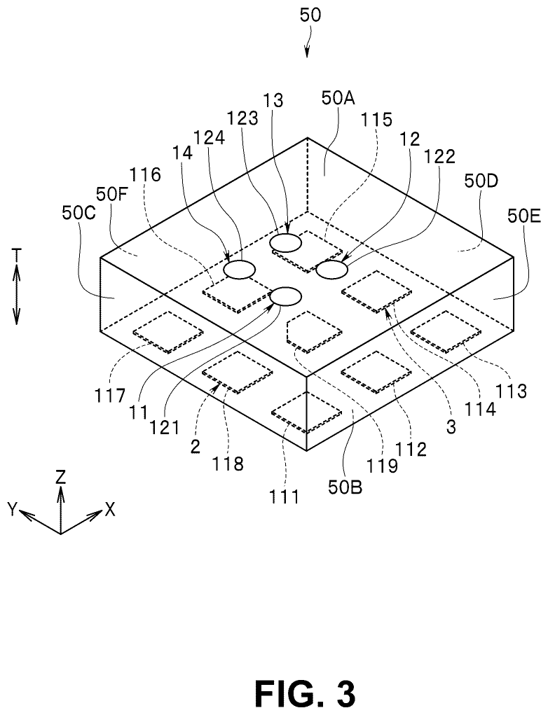

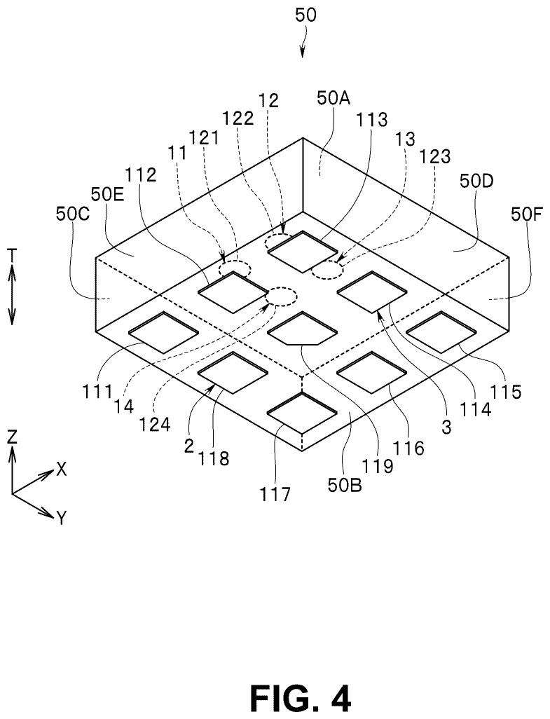

Next, other configurations of the electronic component 1 will be described with reference to FIGS. 2 to 4. FIG. 2 is a perspective view showing the electronic component 1. FIGS. 3 and 4 are each a perspective view showing a first main body.

The electronic component 1 includes a first main body 50. The first main body 50 includes a plurality of dielectric layers stacked together and a plurality of conductors (a plurality of conductor layers and a plurality of through holes). The first main body 50 also includes the first circuit including the inductors L1 to L7 and the capacitors C1 to C11 shown in FIG. 1. The inductors L1 to L7 and the capacitors C1 to C11 are constituted using a plurality of conductors. Each of the plurality of dielectric layers is formed by a dielectric material. As the dielectric material, low-temperature co-fired ceramics (LTCC) is used, for example.

The first main body 50 includes a first surface 50A and a second surface 50B located at opposite ends of the plurality of dielectric layers in the stacking direction T, and four side surfaces 50C to 50F connecting the first surface 50A and the second surface 50B. The side surfaces 50C and 50D are opposite to each other, and the side surfaces 50E and 50F are also opposite to each other. The side surfaces 50C to 50F are each perpendicular to both of the first surface 50A and the second surface 50B.

Here, an X direction, a Y direction, and a Z direction will be defined as shown in FIGS. 2 to 4. The X direction, the Y direction, and the Z direction are orthogonal to one another. In the example embodiment, one direction parallel to the stacking direction T is referred to as the Z direction. The opposite directions to the X, Y, and Z directions are defined as −X, −Y, and −Z directions, respectively. The expression “when viewed in a predetermined direction (e.g., the Z direction)” means that an object is viewed from a position away in a predetermined direction or in one direction parallel to the predetermined direction.

As shown in FIGS. 3 and 4, the first surface 50A is located at an end of the first main body 50 in the Z direction. The first surface 50A is also a top surface of the first main body 50 and is also a mounting surface for mounting a second main body to be described below. The second surface 50B is located at an end of the first main body 50 in the −Z direction. The second surface 50B is also a bottom surface of the first main body 50. FIG. 3 shows the first main body 50 in a view from the first surface 50A side. FIG. 4 shows the first main body 50 in a view from the second surface 50B side.

The side surface 50C is located at an end of the first main body 50 in the −X direction. The side surface 50D is located at an end of the first main body 50 in the X direction. The side surface 50E is located at an end of the first main body 50 in the −Y direction. The side surface 50F is located at an end of the first main body 50 in the Y direction.

The first main body 50 further includes a plurality of electrodes 111, 112, 113, 114, 115, 116, 117, 118, and 119 provided on the second surface 50B of the first main body 50. The electrodes 111, 112, and 113 are arranged in this order in the X direction at positions closer to the side surface 50E than to the side surface 50F. The electrodes 115, 116, and 117 are arranged in this order in the −X direction at positions closer to the side surface 50F than to the side surface 50E.

The electrode 114 is disposed between the electrode 113 and the electrode 115. The electrode 118 is disposed between the electrode 111 and the electrode 117. The electrode 119 is disposed between the electrode 112 and the electrode 116. The electrode 119 is also disposed at the approximate center of the second surface 50B.

The electrode 118 corresponds to the first input and output terminal 2. The electrode 114 corresponds to the second input and output terminal 3. Therefore, the first and second input and output terminals 2 and 3 are provided on the second surface 50B of the first main body 50. Each of the electrodes 111, 112, 113, 115, 116, 117, and 119 is connected to the ground.

The first main body 50 further includes a plurality of electrodes 121, 122, 123, and 124 provided on the first surface 50A of the first main body 50. The electrodes 121 and 122 are arranged in this order in the X direction at positions closer to the side surface 50E than to the side surface 50F. The electrodes 123 and 124 are arranged in this order in the −X direction at positions closer to the side surface 50F than to the side surface 50E.

The electrode 121 corresponds to the signal terminal 11. The electrode 122 corresponds to the signal terminal 12. The electrode 123 corresponds to the signal terminal 13. The electrode 124 corresponds to the signal terminal 14. Therefore, the signal terminals 11 to 14 are provided on the first surface 50A of the first main body 50.

The electronic component 1 further includes a second main body 80 mounted on the first surface 50A of the first main body 50. The second main body 80 includes the second circuit including the acoustic wave elements 31 and 32 shown in FIG. 1.

The second main body 80 further includes four electrodes constituting the signal terminals 81, 82, 83, and 84, respectively. Note that in FIG. 2, the four electrodes are shown denoted with the reference numerals 81 to 84 for convenience. In a state where the second main body 80 is mounted on the first main body 50, the four electrodes denoted with the reference numerals 81 to 84 respectively face the electrodes 121 to 124 of the first main body 50. The four electrodes denoted with the reference numerals 81 to 84 are physically connected to the electrodes 121 to 124 each by a solder bump 7, for example.

In the example shown in FIG. 2, the second main body 80 is disposed so as to overlap the center of gravity of the first surface 50A when viewed in the stacking direction T. The center of gravity of the second main body 80 when viewed in the stacking direction T may or may not coincide with the center of gravity of the first surface 50A.

The electronic component 1 further includes a sealing portion 90 that seals the second main body 80. The sealing portion 90 covers the perimeter of the second main body 80 and at least a part of the first surface 50A of the first main body 50. The sealing portion 90 may further cover the side surfaces 50C to 50F of the first main body 50. The sealing portion 90 is formed of resin, for example.

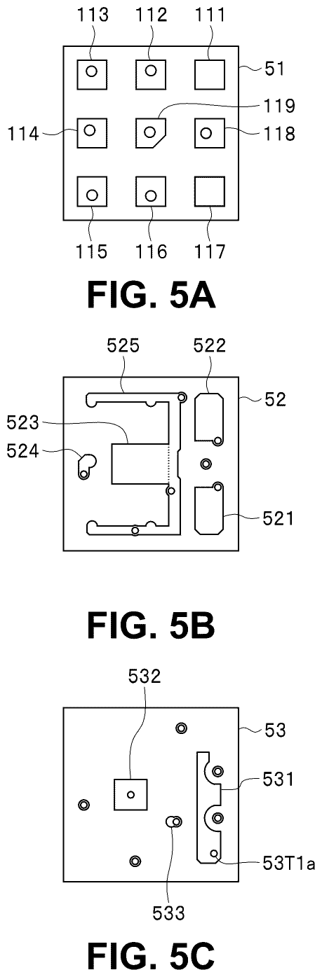

Next, an example of the plurality of dielectric layers, the plurality of conductor layers, and the plurality of through holes constituting the first main body 50 will be described with reference to FIGS. 5A to 10C. In this example, the first main body 50 includes nineteen dielectric layers stacked together. The nineteen dielectric layers are hereinafter referred to as first to nineteenth dielectric layers in the order from bottom to top. The first to nineteenth dielectric layers are denoted by the reference numerals 51 to 69, respectively.

In FIGS. 5A to 10B, a plurality of circles represent a plurality of through holes. Each of the dielectric layers 51 to 69 has a plurality of through holes formed. Each of the plurality of through holes is formed by filling a hole intended for a through hole with a conductive paste. Each of the plurality of through holes is connected to an electrode, a conductor layer, or another through hole.

In FIGS. 5A to 10B, a plurality of specific through holes out of the plurality of through holes are denoted by reference numerals. Regarding the connection relation between each of the plurality of specific through holes and an electrode, a conductor layer, or another through hole, a connection relation in a state that the first to nineteenth dielectric layers 51 to 69 are stacked together is described.

FIG. 5A shows a patterned surface of the first dielectric layer 51. The electrodes 111 to 119 are formed on the patterned surface of the dielectric layer 51.

FIG. 5B shows a patterned surface of the second dielectric layer 52. Conductor layers 521, 522, 523, 524, and 525 are formed on the patterned surface of the dielectric layer 52. The conductor layer 525 is connected to the conductor layer 523. In FIG. 5B, the boundary between the conductor layer 523 and the conductor layer 525 is indicated by a dotted line.

FIG. 5C shows a patterned surface of the third dielectric layer 53. Conductor layers 531, 532, and 533 are formed on the patterned surface of the dielectric layer 53. In FIG. 5C, a through hole denoted by the reference numeral 53T1a is connected to the conductor layer 531. Note that in the following description, the through hole denoted by the reference numeral 53T1a is simply referred to as a through hole 53T1a. Such manner for the through hole 53T1a similarly applies to through holes denoted by reference numerals other than the through hole 53T1a.

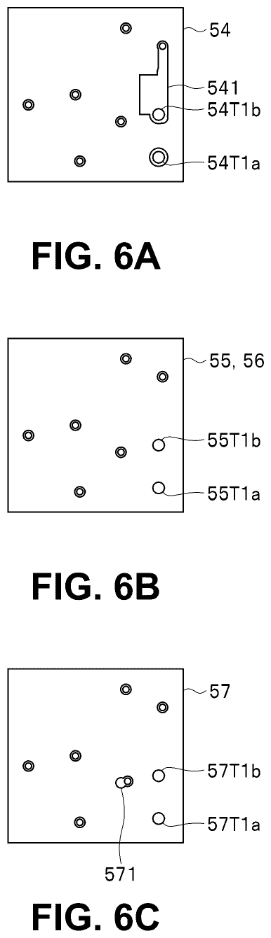

FIG. 6A shows a patterned surface of the fourth dielectric layer 54. A conductor layer 541 is formed on the patterned surface of the dielectric layer 54. A through hole 54T1b shown in FIG. 6A is connected to the conductor layer 541. The through hole 53T1a is connected to a through hole 54T1a shown in FIG. 6A.

FIG. 6B shows a patterned surface of each of the fifth and sixth dielectric layers 55 and 56. The through holes 54T1a and 54T1b are respectively connected to through holes 55T1a and 55T1b formed in the dielectric layer 55. In the dielectric layers 55 and 56, vertically adjacent through holes of the same the reference numeral are connected to each other.

FIG. 6C shows a patterned surface of the seventh dielectric layer 57. A conductor layer 571 is formed on the patterned surface of the dielectric layer 57. The through holes 55T1a and 55T1b formed in the dielectric layer 56 are respectively connected to through holes 57T1a and 57T1b shown in FIG. 6C.

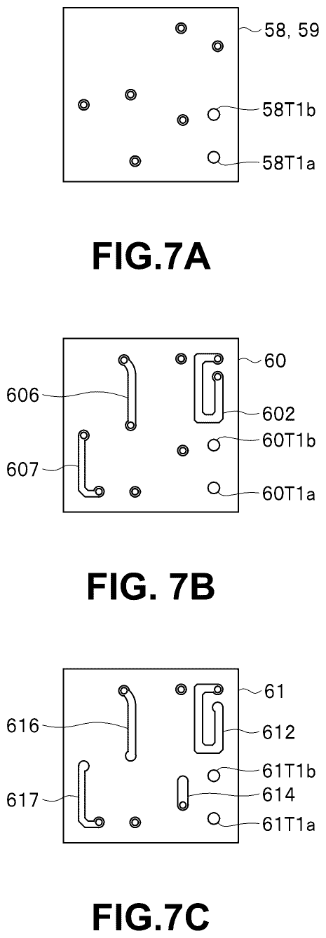

FIG. 7A shows a patterned surface of each of the eighth and ninth dielectric layers 58 and 59. The through holes 57T1a and 57T1b are respectively connected to through holes 58T1a and 58T1b formed in the dielectric layer 58. In the dielectric layers 58 and 59, vertically adjacent through holes of the same the reference numeral are connected to each other.

FIG. 7B shows a patterned surface of the tenth dielectric layer 60. Inductor conductor layers 602, 606, and 607 are formed on the patterned surface of the dielectric layer 60. The through holes 58T1a and 58T1b formed in the dielectric layer 59 are respectively connected to through holes 60T1a and 60T1b shown in FIG. 7B.

FIG. 7C shows a patterned surface of the eleventh dielectric layer 61. Inductor conductor layers 612, 614, 616, and 617 are formed on the patterned surface of the dielectric layer 61. The through holes 60T1a and 60T1b are respectively connected to through holes 61T1a and 61T1b shown in FIG. 7C.

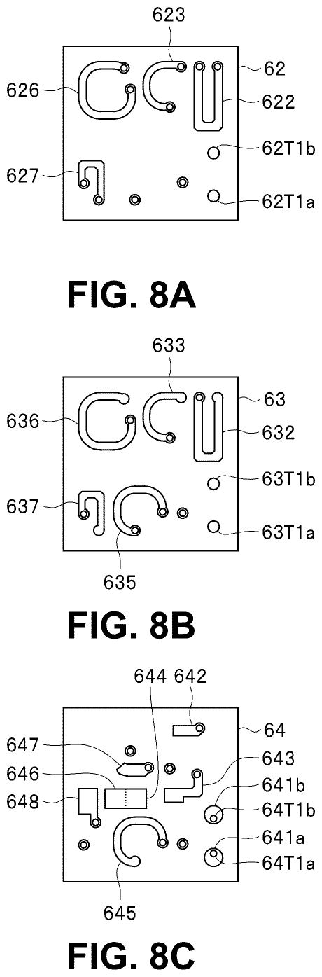

FIG. 8A shows a patterned surface of the twelfth dielectric layer 62. Inductor conductor layers 622, 623, 626, and 627 are formed on the patterned surface of the dielectric layer 62. The through holes 61T1a and 61T1b are respectively connected to through holes 62T1a and 62T1b shown in FIG. 8A.

FIG. 8B shows a patterned surface of the thirteenth dielectric layer 63. Inductor conductor layers 632, 633, 635, 636, and 637 are formed on the patterned surface of the dielectric layer 63. The through holes 62T1a and 62T1b are respectively connected to through holes 63T1a and 63T1b shown in FIG. 8B.

FIG. 8C shows a patterned surface of the fourteenth dielectric layer 64. Conductor layers 641a, 641b, 642, 643, 644, 646, 647, and 648, and an inductor conductor layer 645 are formed on the patterned surface of the dielectric layer 64. The conductor layer 646 is connected to the conductor layer 644. In FIG. 8C, the boundary between the conductor layer 644 and the conductor layer 646 is indicated by a dotted line. The through hole 63T1a and a through hole 64T1a that is shown in FIG. 8C are connected to the conductor layer 641a. The through hole 63T1b and a through hole 64T1b that is shown in FIG. 8C are connected to the conductor layer 641b.

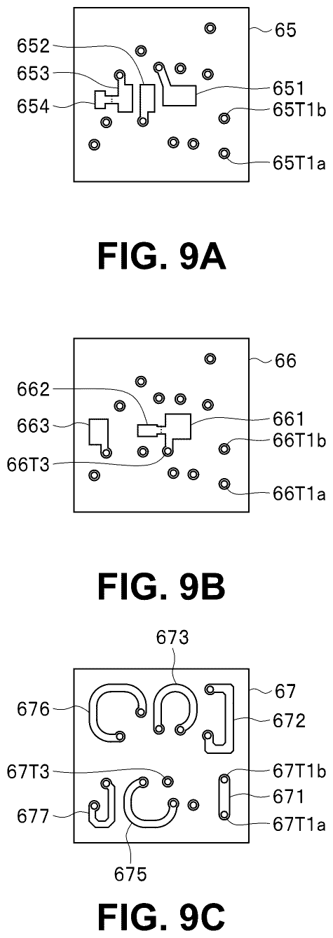

FIG. 9A shows a patterned surface of the fifteenth dielectric layer 65. Conductor layers 651, 652, 653, and 654 are formed on the patterned surface of the dielectric layer 65. The conductor layer 654 is connected to the conductor layer 653. In FIG. 9A, the boundary between the conductor layer 653 and the conductor layer 654 is indicated by a dotted line. The through holes 64T1a and 64T1b are respectively connected to through holes 65T1a and 65T1b shown in FIG. 9A.

FIG. 9B shows a patterned surface of the sixteenth dielectric layer 66. Conductor layers 661, 662, and 663 are formed on the patterned surface of the dielectric layer 66. The conductor layer 662 is connected to the conductor layer 661. In FIG. 9B, the boundary between the conductor layer 661 and the conductor layer 662 is indicated by a dotted line. The through holes 65T1a and 65T1b are respectively connected to through holes 66T1a and 66T1b shown in FIG. 9B. A through hole 66T3 shown in FIG. 9B is connected to the conductor layer 661.

FIG. 9C shows a patterned surface of the seventeenth dielectric layer 67. Inductor conductor layers 671, 672, 673, 675, 676, and 677 are formed on the patterned surface of the dielectric layer 67. The conductor layer 671 has a first end and a second end located opposite to each other in the longitudinal direction of the conductor layer 671. The through hole 66T1a and a through hole 67T1a that is shown in FIG. 9C are connected to a part near the first end of the conductor layer 671. The through hole 66T1b and a through hole 67T1b that is shown in FIG. 9C are connected to a part near the second end of the conductor layer 671. The through hole 66T3 is connected to a through hole 67T3 shown in FIG. 9C.

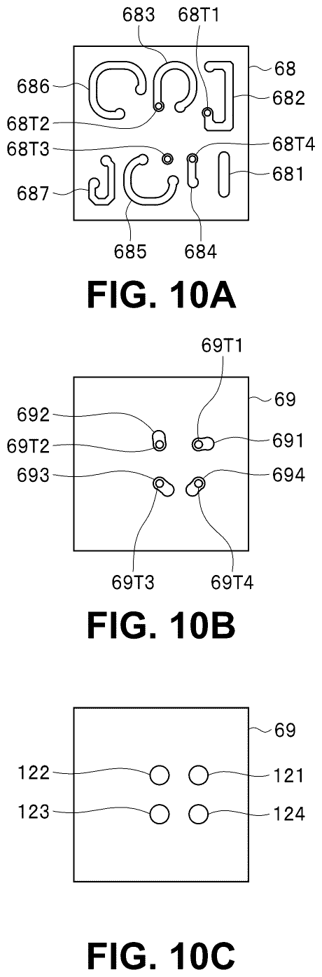

FIG. 10A shows a patterned surface of the eighteenth dielectric layer 68. Inductor conductor layers 681, 682, 683, 684, 685, 686, and 687 are formed on the patterned surface of the dielectric layer 68. The conductor layers 681 has a first end and a second end located opposite to each other in the longitudinal direction of the conductor layers 681. The through hole 67T1a is connected to a part near the first end of the conductor layer 681. The through hole 67T1b is connected to a part near the second end of the conductor layer 681. Through holes 68T1, 68T2, and 68T4 shown in FIG. 10A are connected to the conductor layers 682, 683, and 684, respectively. The through hole 67T3 is connected to a through hole 68T3 shown in FIG. 10A.

FIG. 10B shows a patterned surface of the nineteenth dielectric layer 69. Conductor layers 691, 692, 693, and 694 are formed on the patterned surface of the dielectric layer 69. The through hole 68T1 and a through hole 69T1 that is shown in FIG. 10B are connected to the conductor layer 691. The through hole 68T2 and a through hole 69T2 that is shown in FIG. 10B are connected to the conductor layer 692. The through hole 68T3 and a through hole 69T3 that is shown in FIG. 10B are connected to the conductor layer 693. The through hole 68T4 and a through hole 69T4 that is shown in FIG. 10B are connected to the conductor layer 694.

FIG. 10C shows a surface of the nineteenth dielectric layer 69 opposite to the patterned surface thereof. The surface of the dielectric layer 69 opposite to the patterned surface thereof is hereinafter referred to as an electrode formation surface of the dielectric layer 69. The electrodes 121, 122, 123, and 124 are formed on the electrode formation surface of the dielectric layer 69. The through holes 69T1, 69T2, 69T3, and 69T4 are connected to the electrodes 121, 122, 123, and 124, respectively.

The first main body 50 includes the first to nineteenth dielectric layers 51 to 69 stacked together such that the patterned surface of the first dielectric layer 51 serves as the second surface 50B of the first main body 50 and the electrode formation surface of the nineteenth dielectric layer 69 serves as the first surface 50A of the first main body 50.

Each of the plurality of through holes shown in FIGS. 5A to 10B is connected to a conductor layer that the each through hole overlaps with in the stacking direction T or to another through hole that the each through hole overlaps with in the stacking direction T when the first to nineteenth dielectric layers 51 to 69 are stacked together. Of the plurality of through holes shown in FIGS. 5A to 10B, a through hole located within an electrode or within a conductor layer is connected to the electrode or the conductor layer.

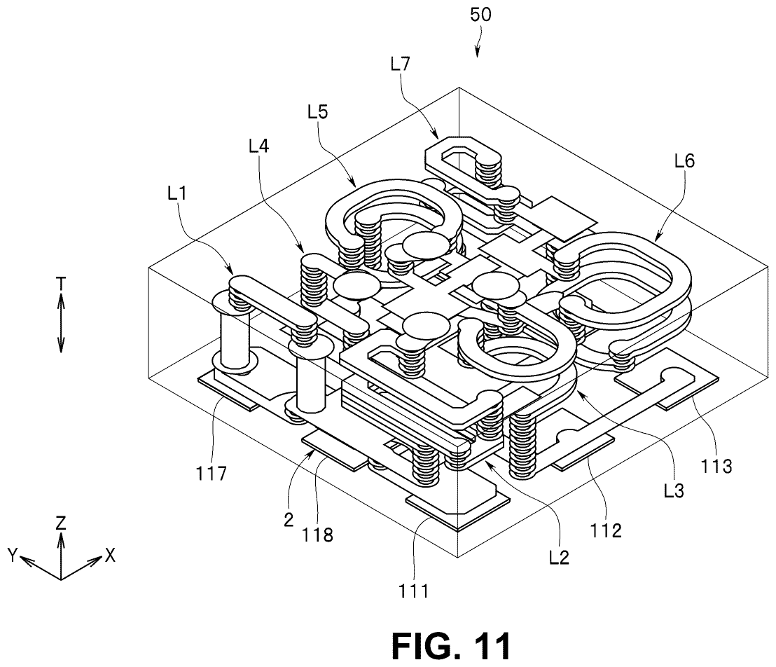

FIG. 11 shows inside of the first main body 50 constituted by the first to nineteenth dielectric layers 51 to 69 stacked together. As shown in FIG. 11, inside the first main body 50, the plurality of conductor layers and the plurality of through holes shown in FIGS. 5A to 10C are stacked together.

The following describes correspondences between the components of the circuit of the electronic component 1 shown in FIG. 1 and the components inside the first main body 50 shown in FIGS. 5A to 10C. The inductor L1 includes the inductor conductor layers 671 and 681, the conductor layers 641a and 641b, and the through holes 53T1a, 54T1a, 54T1b, 55T1a, 55T1b, 57T1a, 57T1b, 58T1a, 58T1b, 60T1a, 60T1b, 61T1a, 61T1b, 62T1a, 62T1b, 63T1a, 63T1b, 64T1a, 64T1b, 65T1a, 65T1b, 66T1a, 66T1b, 67T1a, and 67T1b.

The inductor L2 includes the inductor conductor layers 602, 612, 622, 632, 672, and 682, and a plurality of through holes connecting these conductor layers. The conductor layer 682 is connected to the electrode 121 via the through hole 68T1, the conductor layer 691, and the through hole 69T1.

The inductor L3 includes the inductor conductor layers 623, 633, 673, and 683, and a plurality of through holes connecting these conductor layers. The conductor layer 683 is connected to the electrode 122 via the through hole 68T2, the conductor layer 692, and the through hole 69T2.

The inductor L4 includes the inductor conductor layers 614 and 684, the conductor layers 533 and 571, a plurality of through holes connecting the conductor layers 614 and 684, a plurality of through holes connecting the conductor layers 571 and 614, a plurality of through holes connecting the conductor layers 533 and 571, and a plurality of through holes connecting the conductor layers 525 and 533. The conductor layer 684 is connected to the electrode 124 via the through hole 68T4, the conductor layer 694, and the through hole 69T4.

The inductor L5 includes the inductor conductor layers 635, 645, 675, and 685, and a plurality of through holes connecting these conductor layers. The inductor L6 includes the inductor conductor layers 606, 616, 626, 636, 676, and 686, and a plurality of through holes connecting these conductor layers. The inductor L7 includes the inductor conductor layers 607, 617, 627, 637, 677, and 687, and a plurality of through holes connecting these conductor layers.

The capacitor C1 includes the conductor layers 521, 522, 531, and 541, and the dielectric layers 52 and 53 interposed between these conductor layers. The capacitor C2 includes the electrodes 111 and 117, the conductor layers 521 and 522, and the dielectric layer 51 interposed between the electrodes 111 and 117 and the conductor layers 521 and 522.

The capacitor C3 includes the conductor layers 633 and 642, and the dielectric layer 63 interposed between these conductor layers. The capacitor C4 includes the conductor layers 643 and 651, and the dielectric layer 64 interposed between these conductor layers.

The capacitor C5 includes the conductor layers 651 and 661, and the dielectric layer 65 interposed between these conductor layers. The conductor layer 661 is connected to the electrode 123 via the through holes 66T3, 67T3, and 68T3, the conductor layer 693, and the through hole 69T3.

The capacitor C6 includes the conductor layers 652 and 662, and the dielectric layer 65 interposed between these conductor layers. The capacitor C7 includes the conductor layers 644 and 652, and the dielectric layer 64 interposed between these conductor layers. The capacitor C8 includes the conductor layers 646 and 653, and the dielectric layer 64 interposed between these conductor layers. The capacitor C9 includes the conductor layers 636 and 647, and the dielectric layer 63 interposed between these conductor layers.

The capacitor C10 includes the conductor layers 523 and 532, and the dielectric layer 52 interposed between these conductor layers. The capacitor C11 includes the conductor layers 648, 654, and 663, and the dielectric layers 64 and 65 each interposed between these conductor layers.

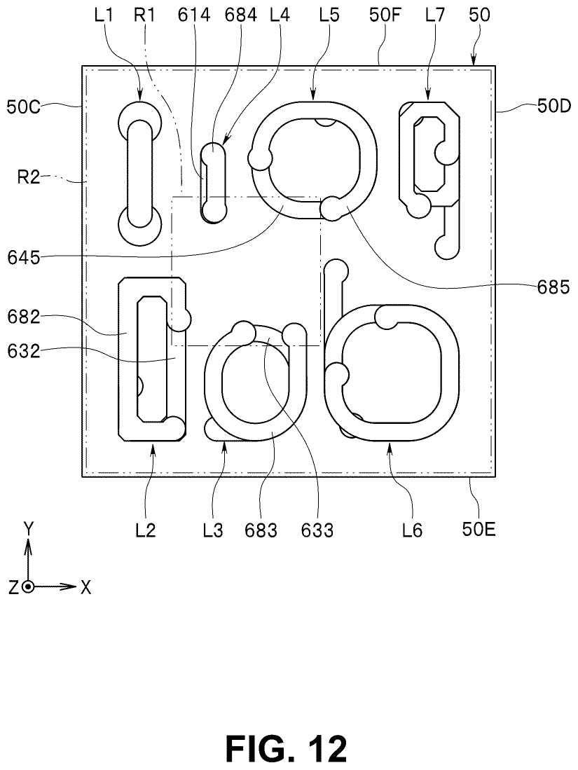

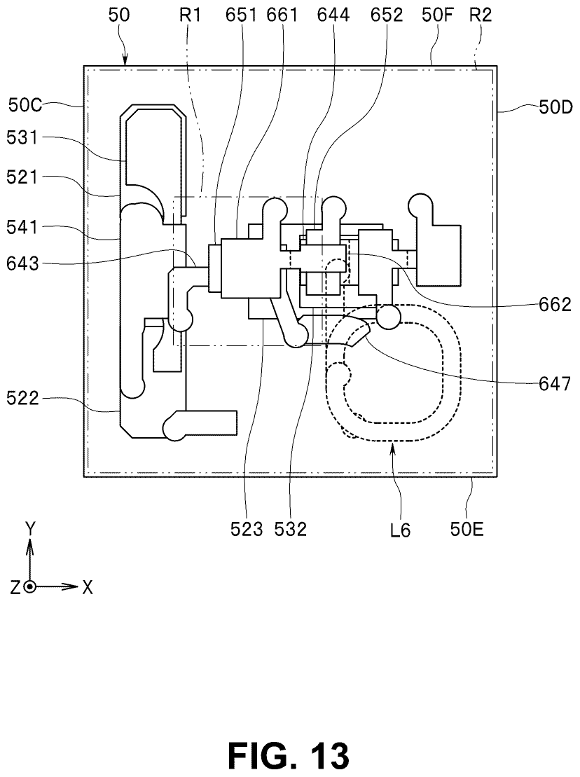

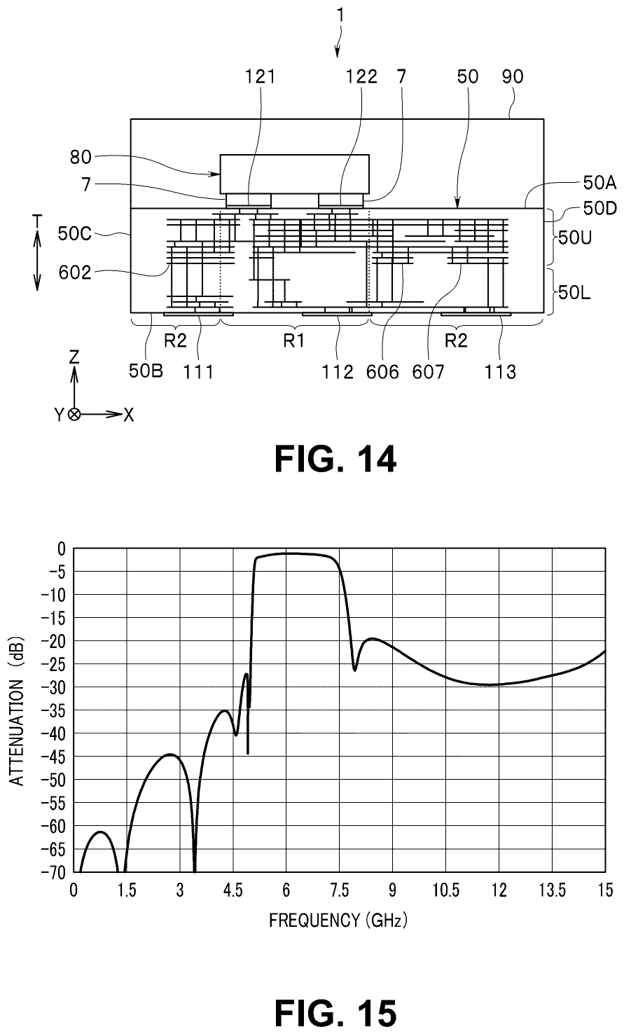

Next, structural features of the electronic component 1 according to the example embodiment will be described with reference to FIGS. 2 to 14. FIGS. 12 and 13 are each a plan view showing a part of inside of the first main body 50. FIG. 14 is a sectional view showing the electronic component 1. Note that in FIG. 12, a plurality of conductor layers constituting the inductor are shown in solid lines. In FIG. 13, the conductor layers constituting the capacitor are shown in solid lines, and the conductors constituting the inductor L6 are shown in dashed lines. In FIG. 14, the plurality of conductors of the first main body 50 are shown.

First, two regions of the first main body 50 defined by the second main body 80 will be described. As previously mentioned, the second main body 80 is mounted on the first surface 50A of the first main body 50. The first main body 50 includes a first region R1 that overlaps the second main body 80 when viewed in the stacking direction T, and a second region R2 that does not overlap the second main body 80 when viewed in the stacking direction T. The first region R1 is defined as a three-dimensional region with an end in the Z direction present on the first surface 50A and an end in the −Z direction present on the second surface 50B. In FIGS. 12 and 13, an outer edge portion of the first region R1, including an end in the X direction, an end in the −X direction, an end in the Y direction, and an end in the −Y direction of the first region R1, is shown by a rectangular double-dashed line denoted with the reference numeral R1.

The second region R2 is substantially defined as a region obtained by excluding the first region R1 from the three-dimensional region enclosed by the outer circumferential surfaces of the first main body 50. The second region R2 covers at least a part of an outer circumferential portion of the first region R1. In the example embodiment in particular, the second region R2 covers parts of the outer circumferential portion of the first region R1, excluding an end in the Z direction (the first surface 50A) and an end in the −Z direction (the second surface 50B). In FIGS. 12 and 13, an outer edge portion of the second region R2, including an end in the X direction, an end in the −X direction, an end in the Y direction, and an end in the −Y direction of the second region R2, is shown by a rectangular double-dashed line denoted with the reference numeral R2. Note that in FIGS. 12 and 13, the outer edge portion of the second region R2 is drawn away from the side surfaces 50C to 50F of the first main body 50 for convenience. In FIG. 14, the boundary between the first region R1 and the second region R2 is shown by a dotted line.

A planar shape of the second main body 80 (shape when viewed in the stacking direction T) may be the same as the shape of the first region R1. Alternatively, the second main body 80 may include a first part having a planar shape that is the same as the shape of the first region R1 and a second part having a planar shape having a size different from the size of the planar shape of the first region R1. In this case, the second main body 80 is mounted on the first main body 50 in a posture where the first part is located between the first main body 50 and the second part.

Next, a relationship between the plurality of conductors of the first main body 50 and the first and second regions R1 and R2 is described. Here, of the plurality of conductors, a plurality of conductors to constitute at least one capacitor are also referred to as a plurality of capacitor conductors. In the example embodiment in particular, the at least one capacitor conductor includes a plurality of capacitor conductors.

As shown in FIG. 13, at least a part of the plurality of capacitor conductors is disposed in the first region R1. In the example embodiment in particular, in a part of the first region R1, which is closer to the first surface 50A than to the second surface 50B, there are disposed a part of the conductor layer 643 constituting the capacitor C4, the entirety of the conductor layer 651 constituting the capacitors C4 and C5, the entirety of the conductor layer 661 constituting the capacitor C5, a part of the conductor layer 662 constituting the capacitor C6, a part of the conductor layer 652 constituting the capacitors C6 and C7, and a part of the conductor layer 644 constituting the capacitor C7. In a part of the first region R1, which is closer to the second surface 50B than to the first surface 50A, there are disposed a part of each of the conductor layers 521, 522, 531, and 541 constituting the capacitor C1, and a part of each of the conductor layers 523 and 532 constituting the capacitor C10.

Of the plurality of the capacitor conductors, parts other than the part disposed in the first region R1 are disposed in the second region R2.

In the first main body 50, no other inductors and no other capacitors are provided between the part of the plurality of capacitor conductors, which is disposed in the first region R1, and the second main body 80. The other capacitors mean capacitors other than the plurality of capacitors constituted by the above-described part disposed in the first region R1.

Of the plurality of conductors, at least one conductor to constitute at least one inductor is also referred to as at least one inductor conductor. In the example embodiment in particular, the at least one inductor includes a plurality of inductors, and the at least one inductor conductor includes a plurality of inductor conductors. The plurality of inductor conductors include the plurality of inductor conductor layers described above, a plurality of through holes for connecting the plurality of inductor conductor layers, and a plurality of conductor layers connected to the plurality of through holes.

The plurality of inductor conductors constituting the inductor L2 are wound around an axis extending in a direction parallel to the stacking direction T so that an opening portion surrounded by the plurality of inductor conductors is formed. Hereinafter, the opening portion surrounded by the plurality of inductor conductors constituting the inductor L2 is referred to as an opening portion of the inductor L2. The opening portion of the inductor L2 faces the first surface 50A of the first main body 50. An entirety of the opening portion of the inductor L2 is present in the second region R2. Hereinafter, also for inductors other than the inductor L2, the opening portion surrounded by the plurality of conductors constituting the inductor is referred to as an opening portion of the inductor.

Similarly, a plurality of inductor conductors constituting each of the inductors L3, L5, L6, and L7 are wound around an axis extending in a direction parallel to the stacking direction T so that an opening portion surrounded by the plurality of inductor conductors is formed. The opening portion of each of the inductors L3, L5, L6, and L7 faces the first surface 50A of the first main body 50. A major part of the opening portion of each of the inductors L3 and L5 is present in the second region R2. An entirety of the opening portion of each of the inductors L6 and L7 is present in the second region R2.

The following describes a plurality of inductor conductors constituting each of the inductors L2, L3, L5, L6, and L7. In the following descriptions, a simple reference to a plurality of inductor conductors without limiting the inductors refers to a plurality of inductor conductors constituting any inductor of the inductors L2, L3, L5, L6, and L7.

Here, the plurality of inductor conductors will be described, focusing on a magnetic field generated by the inductor. The plurality of inductor conductors include at least one major part that contributes to generating the magnetic field, and at least one non-major part. The at least one major part is, for example, a wound part that is wound so as to surround the periphery of the opening portion of the inductor, or a major part of the wound part.

The at least one non-major part is a part that makes no or little contribution to generating a magnetic field or makes less contribution to generating a magnetic field than the at least one major part does. The at least one non-major part is, for example, a part that does not surround the periphery of the opening portion of the inductor, or a relatively short part of a part of the wound part, which does not substantially surround the opening portion of the inductor.

The at least one major part of the plurality of inductor conductors is disposed in the second region R2. The at least one non-major part of the plurality of inductor conductors is disposed in the second region R2, or is disposed at least in part in the first region R1. In the example embodiment in particular, the at least one non-major part of the plurality of inductor conductors constituting each of the inductors L2, L3, and L5 is disposed at least in part in the first region R1. Specifically, a part (relatively short part) of each of the inductor conductor layers 602, 612, 622, 632, 672, and 682 constituting the inductor L2 is disposed in the first region R1. A part (relatively short part) of each of the inductor conductor layers 623, 633, 673, and 683 constituting the inductor L3 is disposed in the first region R1. A part (relatively short part) of each of the inductor conductor layers 635 and 645 constituting the inductor L5 is disposed in the first region R1.

At least one other non-major part of the plurality of inductor conductors constituting each of the inductors L2, L3, and L5 may be disposed in the second region R2. At least one non-major part of the plurality of inductor conductors constituting each of the inductors L6 and L7 is disposed in the second region R2.

Here, the first main body 50 is divided into an upper layer portion 50U and a lower layer portion 50L, as shown in FIG. 14. The upper layer portion 50U and the lower layer portion 50L are divided based on the inductor conductor layers 602, 606, and 607 that are the closest to the second surface 50B, among the plurality of inductor conductors. In other words, a part of the first main body 50, which includes the dielectric layers 60 to 69 located between the conductor layers 602, 606, and 607 and the first surface 50A is the upper layer portion 50U. A part of the first main body 50, which includes the dielectric layers 51 to 59 located between the conductor layers 602, 606, and 607 and the second surface 50B is the lower layer portion 50L.

As mentioned above, the plurality of major parts of the plurality of inductor conductors are not disposed in the first region R1. However, a part of the plurality of major parts of the plurality of inductor conductors may be disposed in a part of the first region R1, which belongs to the lower layer portion 50L. In this case, a part of the plurality of capacitor conductors, which is disposed in the first region R1, is interposed between a part of the plurality of major parts and the second main body 80.

Note that the size of the plurality of non-major parts of the plurality of inductor conductors, which are disposed in the first region R1, may be small. The size of the plurality of non-major parts in the first region R1 may be based on the part of the plurality of capacitor conductors, which is disposed in the first region R1. Here, a planar figure created by vertically projecting the part of the plurality of capacitor conductors, which is disposed in the first region R1, onto the first surface 50A is referred to as a first planar figure, and a planar figure created by vertically projecting the plurality of non-major parts in the first region R1 onto the first surface 50A is referred to as a second planar figure. The first planar figure can be drawn by selectively tracing an outer edge of the part of the plurality of capacitor conductors, which is disposed in the first region R1. Similarly, the second planar figure can be drawn by selectively tracing an outer edge of the plurality of non-major parts in the first region R1. In the example embodiment, an area of the first planar figure may be made larger than an area of the second planar figure, and the size of the plurality of non-major parts of the plurality of inductor conductors disposed in the first region R1 may be made relatively smaller.

Heretofore, the plurality of inductor conductors constituting each of the inductors L2, L3, L5, L6, and L7 have been described. Here, a plurality of inductor conductors constituting the inductor L1 and a plurality of inductor conductors constituting the inductor L4 will be described. The plurality of inductor conductors constituting the inductor L1 are wound around an axis extending in a direction orthogonal to the stacking direction T so that an opening portion surrounded by the plurality of inductor conductors is formed. The opening portion of the inductor L1 faces the side surface 50C of the first main body 50.

The plurality of inductor conductors constituting the inductor L4 are disposed so that the opening portion surrounded by the plurality of inductor conductors is not formed.

In the examples shown in FIGS. 12 and 14, the plurality of inductor conductors constituting the inductor L1 are disposed in the second region R2. A part of the plurality of inductor conductors constituting the inductor L4 is disposed in the second region R2, and another part of the plurality of inductor conductors constituting the inductor L4 is disposed in the first region R1. However, an entirety of the plurality of inductor conductors constituting each of the inductors L1 and L4 may be disposed in the first region R1.

Next, an example of characteristics of the electronic component 1 according to the example embodiment will be described. FIG. 15 is a characteristic chart showing an example of pass attenuation characteristics of the electronic component 1. In FIG. 15, the horizontal axis indicates frequency and the vertical axis indicates attenuation. As shown in FIG. 15, it can be seen that the electronic component 1 has sufficient characteristics for practical use as a band-pass filter.

Next, the operation and effects of the electronic component 1 according to the example embodiment will be described. In the example embodiment, the opening portion of each of the inductors L2, L3, L5, L6, and L7 faces the first surface 50A of the first main body 50, as previously mentioned. For this reason, the magnetic field generated by each of the inductors L2, L3, L5, L6, and L7 can act on the mounted components mounted on the first surface 50A. When the magnetic field generated by each of the inductors L2, L3, L5, L6, and L7 acts on the mounted components, there are cases where the electromagnetic fields interact with each other between each of the inductors L2, L3, L5, L6, and L7 and the mounted components, and the desired characteristics cannot be obtained. For example, if the mounted components include an acoustic wave element, there are cases where the electromagnetic fields interact with each other between each of the inductors L2, L3, L5, L6, and L7 and the acoustic wave element, and the insertion loss of the passband of the band-pass filter increases.

In contrast, in the example embodiment, a plurality of major parts of the plurality of inductor conductors constituting each of the inductors L2, L3, L5, L6, and L7 are disposed in the second region R2 of the first main body 50, which does not overlap the second main body 80 when viewed in the stacking direction T. In the example embodiment in particular, an entirety or a major part of the opening portion of each of the inductors L2, L3, L5, L6, and L7 is present in the second region R2. According to the example embodiment, this enables to restrain the interaction of the electromagnetic fields between each of the inductors L2, L3, L5, L6, and L7 and the second main body 80.

In the example embodiment, by disposing the plurality of major parts of the plurality of inductor conductors in the second region R2, a space for disposing the plurality of conductors is formed in the first region R1 of the first main body 50, which overlaps the second main body 80 when viewed in the stacking direction T. In the example embodiment, a part of the plurality of capacitor conductors is disposed in the above-described space in the first region R1. In such a manner, the example embodiment efficiently utilizes the space within the first main body 50, enabling to miniaturize the electronic component 1.

Note that in the example embodiment, a part of the plurality of non-major parts of the plurality of inductor conductors is disposed in the first region R1. If an area of the planar figure created by vertically projecting the part of the plurality of capacitor conductors, which is disposed in the first region R1, onto the first surface 50A is made larger than an area of the planar figure created by vertically projecting the plurality of non-major parts in the first region R1 onto the first surface 50A, the size of the plurality of non-major parts of the plurality of inductor conductors, which are disposed in the first region R1, becomes relatively smaller. According to the example embodiment, this enables to restrain the interaction of the electromagnetic fields between each of the inductors L2, L3, L5, L6, and L7 and the second main body 80, as well as to efficiently utilize the space within the first main body 50, enabling to miniaturize the electronic component 1.

In the example embodiment, since the interaction of the electromagnetic fields between each of the inductors L1 to L7 and the second main body 80 can be restrained, the distance between the plurality of inductor conductors and the first surface 50A can be made small. According to the example embodiment, this enables to make small the dimension of the first main body 50 in the stacking direction T. According to the example embodiment, by causing the distance between the plurality of capacitor conductors and the first surface 50A to be larger than the distance between the plurality of inductor conductors and the first surface 50A, the interaction of the electromagnetic fields between the plurality of capacitor conductors and the second main body 80 can be restrained.

Next, other effects of the electronic component 1 according to the example embodiment will be described. In the example embodiment, the dielectric material that forms each of the plurality of dielectric layers 51 to 69 is low-temperature co-fired ceramics (LTCC), for example. LTCC is more easily made into a thin film than resin. For this reason, to make comparison with the same number of capacitors, it is enabled to make the first main body 50 smaller when each of the plurality of dielectric layers 51 to 69 is formed of LTCC than when each of the plurality of dielectric layers 51 to 69 is formed of resin.

LTCC has lower hygroscopicity than resin. For this reason, when each of the plurality of dielectric layers 51 to 69 is formed of LTCC, the electronic component 1 with high reliability can be achieved compared to when each of the plurality of dielectric layers 51 to 69 is formed of resin.

Capacitors formed using LTCC have a lower dielectric tangent than those formed using resin. For this reason, when each of the plurality of dielectric layers 51 to 69 is formed of LTCC, it is enabled to achieve the capacitors C1 to C11 having high performance compared to when each of the plurality of dielectric layers 51 to 69 is formed of resin, and as a result, it is enabled to achieve the electronic component 1 having high performance.

### Second Example Embodiment

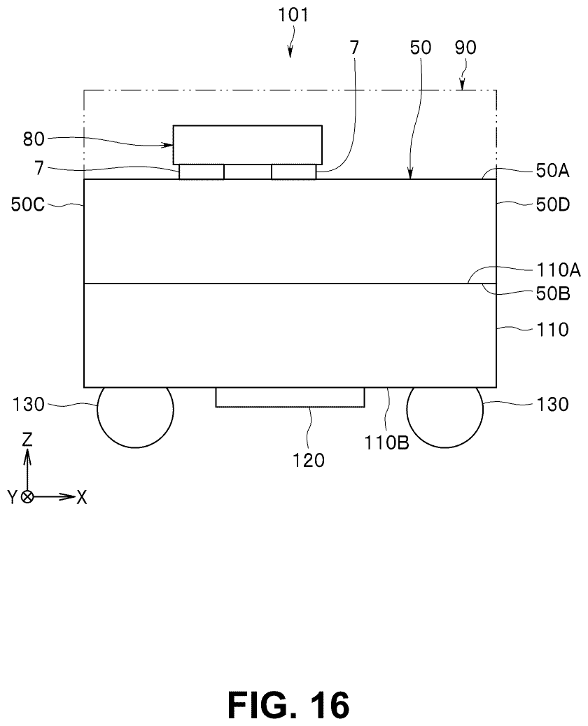

Next, a second example embodiment of the disclosure will be described with reference to FIG. 16. FIG. 16 is a side view showing an electronic component according to the example embodiment.

An electronic component 101 according to the example embodiment includes the first main body 50, the second main body 80, and the sealing portion 90, as in the electronic component 1 according to the first example embodiment. The electronic component 101 further includes a third main body 110 mounted on the second surface 50B of the first main body 50. The planar shape of the third main body 110 may be the same as the planar shape of the first main body 50.

The electronic component 101 includes the first circuit and the second circuit, as in the electronic component 1 according to the first example embodiment. In the example embodiment, the first main body 50 may include the first circuit. In this case, the third main body 110 may include a third circuit connected to the first circuit. Alternatively, the first main body 50 may include a part of the first circuit. In this case, the third main body 110 may include another part of the first circuit.

The third main body 110 has a top surface 110A that faces the second surface 50B of the first main body 50, and a bottom surface 110B opposite to the top surface 110A. The electronic component 101 further includes a fourth main body 120 mounted on the bottom surface 110B of the third main body 110. The fourth main body 120 may be a passive element such as an inductor or capacitor, or may be any active element including a semiconductor, such as a high-frequency switch.

In the example shown in FIG. 16, the bottom surface 110B of the third main body 110 is provided with, in addition to the fourth main body 120, a plurality of solder bumps 130 for connecting the electronic component 101 to a substrate on which the electronic component 101 is to be mounted. The Z-directional dimension of each of the plurality of solder bumps 130 is greater than the Z-directional dimension of the fourth main body 120.

Other configurations, operations, and effects in the example embodiment are the same as those in the first example embodiment.

Note that the disclosure is not limited to the foregoing example embodiments, and various modifications may be made thereto. For example, the electronic component of the disclosure is not limited to a band-pass filter, but can be applied to other filters such as a low-pass filter and a high-pass filter, and to an electronic component that includes a plurality of resonators, such as a branching filter that separates a plurality of signals having different frequency bands.

The second main body 80 may include only one acoustic wave element, or may include three or more acoustic wave elements. The second main body 80 may also include any passive element, such as a capacitor, in addition to the acoustic wave elements 31 and 32. In this case, the passive element may be connected to the acoustic wave element 31 or 32. The second main body 80 may also include any active element including a semiconductor, such as a high-frequency switch, instead of or in addition to the acoustic wave elements 31 and 32.

The second main body 80 may also be disposed near an outer edge of the first surface 50A of the first main body 50.

As described above, an electronic component according to one embodiment of the disclosure includes: a first main body including a plurality of dielectric layers stacked together, a plurality of conductors, and a first circuit constituted using the plurality of conductors; and a second main body including a second circuit connected to the first circuit. The first main body includes a first surface located at an end of the plurality of dielectric layers in a stacking direction. The second main body is mounted on the first surface. The first main body includes a first region that overlaps the second main body when viewed in the stacking direction, and a second region that does not overlap the second main body when viewed in the stacking direction. The plurality of conductors include a plurality of capacitor conductors to constitute at least one capacitor, and at least one inductor conductor to constitute at least one inductor. At least a part of the plurality of capacitor conductors is disposed in the first region. The at least one inductor conductor includes a major part disposed in the second region, and a non-major part. The non-major part is disposed in the second region, or is disposed at least in part in the first region.

In the electronic component according to one embodiment of the disclosure, the first circuit may include the at least one capacitor and the at least one inductor.

In the electronic component according to one embodiment of the disclosure, no other inductors and no other capacitors may be provided between the at least a part of the plurality of capacitor conductors and the second main body.

In the electronic component according to one embodiment of the disclosure, an area of a planar figure created by vertically projecting the at least a part of the plurality of capacitor conductors, the at least a part being disposed in the first region, onto the first surface may be greater than an area of a planar figure created by vertically projecting a part of the non-major part, the part being disposed in the first region, onto the first surface.

In the electronic component according to one embodiment of the disclosure, the at least one capacitor may include a plurality of capacitors. The at least a part of the plurality of capacitor conductors, the at least a part being disposed in the first region, may constitute two or more of the plurality of capacitors.

In the electronic component according to one embodiment of the disclosure, the at least one inductor may include a plurality of inductors. The at least one inductor conductor may include a plurality of inductor conductors.

In the electronic component according to one embodiment of the disclosure, the at least one inductor conductor may be wound around an axis extending in a direction parallel to the stacking direction.

In the electronic component according to one embodiment of the disclosure, the second region may cover at least a part of an outer circumferential portion of the first region.

In the electronic component of the disclosure, the at least a part of the plurality of capacitor conductors is disposed in the first region. The major part of the at least one inductor conductor is disposed in the second region. The non-major part of the at least one inductor conductor is disposed in the second region, or is disposed at least in part in the first region. According to the disclosure, this enables to miniaturize the electronic component while achieving desired characteristics.

Obviously, many modifications and variations of the disclosure are possible in the light of the above teachings. Thus, it is to be understood that, within the scope of the appended claims and equivalents thereof, the disclosure may be practiced in other embodiments than the foregoing example embodiment.

1. An electronic component comprising:
a first main body including a plurality of dielectric layers stacked together, a plurality of conductors, and a first circuit constituted using the plurality of conductors; and
a second main body including a second circuit connected to the first circuit, wherein
the first main body includes a first surface located at an end of the plurality of dielectric layers in a stacking direction,
the second main body is mounted on the first surface,
the first main body includes a first region that overlaps the second main body when viewed in the stacking direction, and a second region that does not overlap the second main body when viewed in the stacking direction,
the plurality of conductors include a plurality of capacitor conductors to constitute at least one capacitor, and at least one inductor conductor to constitute at least one inductor,
at least a part of the plurality of capacitor conductors is disposed in the first region,
the at least one inductor conductor includes a major part disposed in the second region, and a non-major part, and
the non-major part is disposed in the second region, or is disposed at least in part in the first region.

2. The electronic component according to claim 1, wherein the first circuit includes the at least one capacitor and the at least one inductor.

3. The electronic component according to claim 1, wherein no other inductors and no other capacitors are provided between the at least a part of the plurality of capacitor conductors and the second main body.

4. The electronic component according to claim 1, wherein
an area of a planar figure created by vertically projecting the at least a part of the plurality of capacitor conductors, the at least a part being disposed in the first region, onto the first surface is greater than an area of a planar figure created by vertically projecting a part of the non-major part, the part being disposed in the first region, onto the first surface.

5. The electronic component according to claim 1, wherein
the at least one capacitor comprises a plurality of capacitors, and
the at least a part of the plurality of capacitor conductors, the at least a part being disposed in the first region, constitutes two or more of the plurality of capacitors.

6. The electronic component according to claim 1, wherein
the at least one inductor comprises a plurality of inductors, and
the at least one inductor conductor comprises a plurality of inductor conductors.

7. The electronic component according to claim 1, wherein the at least one inductor conductor is wound around an axis extending in a direction parallel to the stacking direction.

8. The electronic component according to claim 1, wherein the second region covers at least a part of an outer circumferential portion of the first region.
